(19) United States
(12) Patent Application Publication
(10) Pub. No.: US 2026/0202307 A1
(43) Pub. Date: Jul. 16, 2026

(54) SENSING DEVICE AND METHOD FOR MANUFACTURING THE SAME

(71) Applicant: INDUSTRIAL TECHNOLOGY RESEARCH INSTITUTE, Hsinchu (TW)

(72) Inventors: Tseng-Huang LIU, Kaohsiung City (TW); Yi-Chau HUANG, Zhudong Township (TW); Chia-Ying TANG, Hsinchu City (TW)

(73) Assignee: INDUSTRIAL TECHNOLOGY RESEARCH INSTITUTE, Hsinchu (TW)

(21) Appl. No.: 19/436,791

(22) Filed: Dec. 30, 2025

Related U.S. Application Data
(60) Provisional application No. 63/739,728, filed on Dec. 30, 2024.

(51) Int. Cl. G01N 15/1434; C09D 133/02; C09D 141/00; C09D 143/02; C23C 14/08; C23C 14/18; C23C 14/48; C23C 16/06; C23C 16/40; C23C 16/455; G01N 15/14

(52) U.S. Cl. CPC G01N 15/1434; C09D 133/02; C09D 141/00; C09D 143/02; C23C 14/081; C23C 14/083; C23C 14/18; C23C 14/48; C23C 16/06; C23C 16/403; C23C 16/405; C23C 16/45525; G01N 2015/1486

(57) ABSTRACT

The present disclosure provides a sensing device. The sensing device includes a substrate, a protective layer and a hole. The substrate has an upper surface. The protective layer is disposed on the substrate and contacts the upper surface. The hole penetrates the protective layer and a portion of the substrate.

This application claims the benefit of U.S. provisional application Ser. No. 63/739,728, filed Dec. 30, 2024, the disclosure of which is incorporated by reference herein in its entirety.

### TECHNICAL FIELD

The disclosure relates to a sensing device and a method for manufacturing the same.

### BACKGROUND

Biosensing chips are widely applied, however, numerous challenges and requirements in technical research and development remain to be addressed. For example, certain substrate materials of biosensing chips (e.g., Si, Si₃N₄, Al₂O₃, HfO₂, certain high-refractive-index oxides, or polymers) exhibit photoluminescence (PL) characteristics, which may generate background signals and interfere with optical sensing detection.

Specifically, materials with photoluminescence characteristics exhibit spontaneous emission from intrinsic or defect energy levels when excited by laser or high-energy light sources. These photoluminescence signals are often distributed within the visible light spectrum and may overlap with the emission bands of fluorescent labels or biomolecule markers, resulting in high background noise and a reduced signal-to-noise ratio (SNR), thereby affecting sensing accuracy.

Moreover, in the detection on the surface of biosensing chips, non-specific adsorption of biomolecules also affects sensing results. Proteins or enzymes tend to form a protein corona on the chip surface, which subsequently masks surface-modified functional molecules (e.g., aptamers or antibodies), leading to a significant decrease in the specific recognition capability for target molecules. Furthermore, non-specifically adsorbed enzymes may undergo inactivation or cause random background catalytic reactions at unintended locations. Regarding peptides and nucleic acids (e.g., DNA), they may adhere to the chip through hydrophobic interactions or electrostatic adsorption (e.g., negatively charged nucleic acids and positively charged surface amine groups), which not only increases background signals but may also lead to false-positive results. Overall, such non-specific adsorption causes large variations between different chips and poor reproducibility, and severely affects the accuracy and reproducibility of quantitative detection (e.g., concentration and signal intensity).

In view of the above, there remains a current need to develop an improved biosensing chip to meet the requirements of reducing photoluminescence characteristics and minimizing non-specific adsorption.

### SUMMARY

The disclosure is directed to a sensing device applied in biomedical detection, wherein photoluminescence can be improved by the provision of a protective layer. Furthermore, the problem of non-specific adsorption can also be resolved by the provision of a passivation layer.

According to some embodiments, a sensing device is provided. The sensing device comprises a substrate, a protective layer and a hole. The substrate has an upper surface. The protective layer is disposed on the substrate and contacts the upper surface. The hole penetrates the protective layer and a portion of the substrate.

According to some embodiments, a sensing device is provided. The sensing device comprises a substrate, a protective layer, a passivation layer and a hole. The substrate has an upper surface. The passivation layer is disposed on the substrate and contacts the upper surface. The passivation layer is disposed on the protective layer. The hole penetrates the passivation layer, the protective layer and a portion of the substrate.

According to some embodiments, a method for manufacturing a sensing device is provided. The method comprises the following steps. A substrate is provided. The substrate has an upper surface. A protective layer is formed on the upper surface, and the protective layer contacts the upper surface. A passivation layer is formed on the protective layer. A hole is formed penetrating the passivation layer, the protective layer and a portion of the substrate.

For a better understanding of the above and other embodiments of the present disclosure, specific embodiments are provided below and described in detail in conjunction with the accompanying drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1A-1D illustrate sensing devices according to various embodiments of the present disclosure.

FIGS. 2A and 2B illustrate sensing devices according to various embodiments of the present disclosure.

FIGS. 3A-3D illustrate a method for manufacturing a sensing device according to the present disclosure.

FIGS. 4A-4E illustrate a method for manufacturing the sensing device of FIG. 2A according to an embodiment of the present disclosure.

FIGS. 5A-5D show scanning electron microscope (SEM) images of hole arrays of various embodiments.

FIGS. 6A-6B illustrate the results of photoluminescence characteristics of Comparative Example 1-1 and Examples 1-5 to 1-8.

FIG. 7A shows schematic diagrams of water contact angle tests for Comparative Examples A-1 to A-4 and 2-1 to 5-1, and Examples 2-2 to 2-4, 3-2 to 3-4, 4-2 to 4-4, and 5-2 to 5-4.

FIG. 7B shows schematic diagrams of water contact angle tests for Comparative Examples 6-1 to 11-1 and Examples 6-2 to 6-4, 7-2 to 7-4, 8-2 to 8-4, 9-2 to 9-4, 10-2 to 10-4, and 11-2 to 11-4.

FIG. 7C shows the test results of the water contact angles of various Comparative Examples and Examples.

FIG. 7D illustrates the surface elemental composition analysis of Examples 7-2 and 11-2.

FIG. 8A shows images of the degree of adhesion of protein (bonded to fluorescent beads) for Comparative Example 6-1 and Examples 6-2 to 6-3.

FIG. 8B shows the particle counts of fluorescent beads for Comparative Example 6-1 and Examples 6-2 to 6-3.

FIG. 8C shows the percentage reduction in the degree of adhesion of Examples 6-2 to 6-3 relative to Comparative Example 6-1.

FIG. 9A shows images of the degree of adhesion of protein (bonded to fluorescent beads) for Comparative Examples A-1 and 2-1, and Examples 2-2 to 2-4.

FIG. 9B shows the particle counts of fluorescent beads for Comparative Examples A-1 and 2-1, and Examples 2-2 to 2-4.

FIG. 9C shows the percentage reduction in the degree of adhesion of Examples 2-2 to 2-4 relative to Comparative Example 2-1.

FIG. 10A shows images of the degree of adhesion of protein (bonded to fluorescent beads) for Comparative Examples A-1 and 7-1, and Examples 7-2 to 7-4.

FIG. 10B shows the particle counts of fluorescent beads for Comparative Examples A-1 and 7-1, and Examples 7-2 to 7-4.

FIG. 10C shows the percentage reduction in the degree of adhesion of Examples 7-2 to 7-4 relative to Comparative Example 7-1.

FIG. 11A shows images of the degree of adhesion of protein (bonded to fluorescent beads) for Comparative Example 10-1 and Examples 10-2 to 10-4.

FIG. 11B shows the particle counts of fluorescent beads for Comparative Example 10-1 and Examples 10-2 to 10-4.

FIG. 11C shows the percentage reduction in the degree of adhesion of Examples 10-2 to 10-4 relative to Comparative Example 10-1.

FIG. 12A shows images of the degree of adhesion of protein (bonded to fluorescent beads) for Comparative Example 11-1 and Examples 11-2 to 11-4.

FIG. 12B shows the particle counts of fluorescent beads for Comparative Example 11-1 and Examples 11-2 to 11-4.

FIG. 12C shows the percentage reduction in the degree of adhesion of Examples 11-2 to 11-4 relative to Comparative Example 11-1.

FIG. 13 shows the results of a DNA sequencing-by-synthesis reaction after immobilizing enzymes in nanopores.

FIGS. 14A-14C are schematic diagrams of SEM surface roughness at the early, middle, and late stages of substrate surface treatment, respectively.

FIG. 15 shows an image of a single fluorescent particle entering a hole.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments are described in more detail below with reference to the accompanying drawings. The description and drawings are provided for illustrative purposes only and are not intended to be limiting. For the sake of clarity, some elements and/or symbols may be omitted in some drawings. Additionally, elements in the drawings may not be drawn to scale. It is contemplated that elements and features of one embodiment can be advantageously incorporated into another embodiment without further recitation.

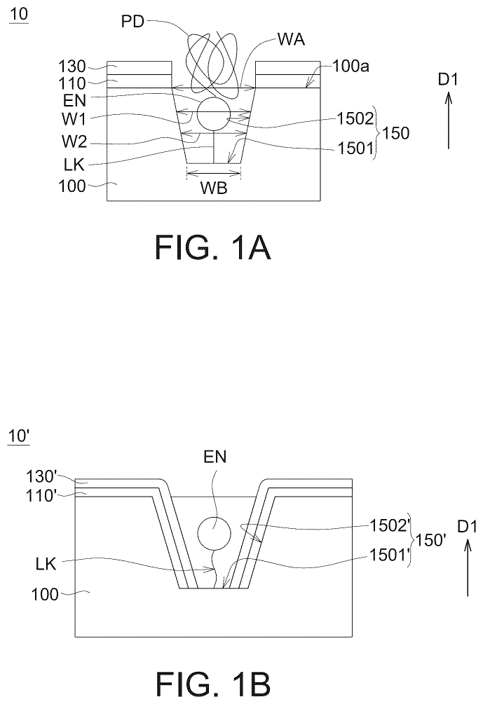

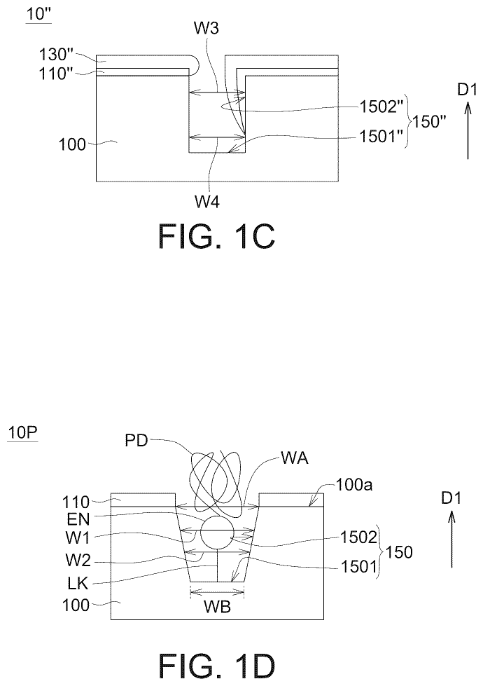

FIGS. 1A-1D illustrate sensing devices 10, 10′, 10″, and 10P, respectively, in accordance with different embodiments of the present disclosure.

Referring to FIGS. 1A and 1D, the sensing devices 10 and 10P comprise a substrate 100 and a protective layer 110, respectively. The substrate 100 has an upper surface 100a. The protective layer 110 is disposed on the substrate 100 and contacts the upper surface 100a. The hole 150 penetrates the protective layer 110 and a portion of the substrate 100.

The protective layer 110 provides protection for the substrate 100 and reduces background interference signals during detection. It can suppress the erosion of the substrate 100 (e.g., a silicon-based substrate) by biomedical reagents containing salts. In addition, the protective layer 110 can also reduce photoluminescence interference from the substrate 100 or the background, diminishing the impact of background values on sensing signals during sensing to improve the quality of sensing results. The holes 150 may include specific modification regions, and the specific modification regions may be configured to immobilize detection substances. The detection substances may include enzymes, proteins, peptides, nucleic acids, or other suitable detection substances. The arrangement of the holes 150 can prevent sensing signals from interfering with each other when adjacent detection substances are too close to one another, which would otherwise make it difficult to distinguish the true signals from each other.

As shown in FIG. 1A, the sensing device 10 further comprises a passivation layer 130. The passivation layer 130 is disposed on the protective layer 110, and the hole 150 further passes through the passivation layer 130. The primary function of the passivation layer 130 is to reduce non-specific adsorption during the detection process. In detail, non-specific adsorption is classified into the following categories: (1) Specific adsorption of proteins or enzymes: Proteins will form a “protein corona” on the surface of the sensing device (chip), masking the original functional modification molecules (e.g., aptamers, antibodies, etc.), resulting in a decrease in specific recognition capability. Enzymes adsorbed at incorrect positions may lose activity or form random background catalytic reactions. (2) Non-specific adsorption of peptides or nucleic acids: Short peptides may adhere to the surface via hydrophobic interactions or charged functional groups, while nucleic acids may cause background through electrostatic adsorption (since DNA is negatively charged, it will adsorb to positively charged amine groups on the surface). It can be seen that non-specific adsorption not only increases the background but may also cause false-positive signals. Furthermore, non-specific adsorption causes significant variations and poor reproducibility between fragments. Quantitative detection (e.g., “molecular concentration” versus “fluorescence intensity”) will become inaccurate. That is, non-specific adsorption affects signal reproducibility and quantification accuracy.

Therefore, the sensing device 10 not only possesses the effects of the aforementioned protective layer 110 and hole 150 but also has the beneficial effect of the passivation layer 130 in reducing non-specific adsorption. Since the primary difference between the sensing devices 10 and 10P lies in the presence or absence of the passivation layer 130, embodiments of the sensing device 10 will be described hereafter, and parts of other sensing device 10P that is identical to the sensing device 10 will not be described in detail again.

According to some embodiments, the hole 150 comprises a bottom surface 1501 and a sidewall 1502, wherein the sidewall 1502 is connected to the bottom surface 1501, and the bottom surface 1501 exposes the substrate 100. In the present embodiment, neither the protective layer 110 nor the passivation layer 130 extends into the hole 150, and the sidewall 1502 also exposes the substrate 100. That is, the protective layer 110 does not cover the sidewall 1502 and is separated from the bottom surface 1501 of the hole 150 without contacting the bottom surface 1501. The substrate 100, the protective layer 110, and the passivation layer 130 overlap each other in a first direction D1, while the protective layer 110 and the passivation layer 130 do not overlap with the hole 150 in the first direction D1. An upper width W1 of the hole 150 is, for example, greater than a lower width W2, having a cross-section similar to an inverted trapezoid; however, the present disclosure is not limited thereto. In other embodiments, the upper width W1 may be equal to the lower width W2.

In the present embodiment, the sensing device 10 further includes a linker LK and a single molecule EN, wherein the single molecule EN is immobilized in the hole 150 through the linker LK. For example, a biotin-binding protein is immobilized on the bottom surface 1501 of the hole 150, one end of the linker LK is immobilized on the bottom surface 1501 of the hole 150 by a silanization immobilization method, and the other end carrying biotin is connected to the single molecule EN via the biotin-binding protein. A product PD may be connected to the single molecule EN. The biotin-binding protein is, for example, Streptavidin, Neutravidin, or another suitable biotin-binding protein. The single molecule EN is, for example, a polymerase, a reverse transcriptase, an enzyme, or another suitable single molecule. The product PD is, for example, a deoxyribonucleic acid (DNA) fragment, complementary deoxyribonucleic acid (cDNA), a ribonucleic acid (RNA) fragment, or another suitable detection product. However, it should be understood that the present disclosure is not limited thereto.

According to some embodiments, the substrate 100 may be a silicon-based substrate. The silicon-based substrate comprises a material, and the material is silicon, silicon dioxide, silicon nitride, or glass.

According to some embodiments, the protective layer 110 comprises a material, and the material is metal oxide, metal, or a combination thereof. The metal oxide is aluminum oxide, titanium dioxide, hafnium dioxide, or any combination thereof. The metal is aluminum, aluminum silicon (AlSi), titanium, chromium, gold, palladium, or any combination thereof. The method for forming the protective layer 110 comprises a deposition process, and the deposition process may be atomic layer deposition (ALD), physical vapor deposition (PVD), or other suitable deposition methods. The protective layer 110 may be a single layer or a multilayer, such as a double-layer protective layer of different materials.

According to some embodiments, the passivation layer 130 comprises a material, and the material is an acidic polymer. The acidic polymer is poly(vinylphosphonic acid) (PVPA), poly(vinylsulfonic acid) (PVSA), or poly(acrylic acid) (PAA).

According to some embodiments, an upper width WA of the hole 150 corresponding to the substrate 100 ranges between 90 nanometers (nm) and 400 nm, such as between 150 nm and 300 nm. A width WB of the bottom surface 1501 of the hole 150 ranges between 70 nm and 400 nm, such as between 90 nm and 110 nm, or between 250 nm and 280 nm. A depth DP1 of the hole 150 corresponding to the substrate 100 is between 300 nm and 400 nm, such as 370 nm.

According to some embodiments, the amount of holes 150 in the sensing device 10 is one. According to other embodiments, the amount of holes 150 in the sensing device 10 is plural, and the holes 150 may be arranged in an array, such as a 10×10 hole array.

According to some embodiments, a water contact angle of the surfaces of the protective layer 110 and the passivation layer 130 is between 1 degree and 60 degrees, such as between 1 degree and 10 degrees.

Referring to FIG. 1B, the sensing device 10′ differs from the sensing device 10 in that the configurations of a protective layer 110′ and a passivation layer 130′ of the sensing device 10′ are different from those of the protective layer 110 and the passivation layer 130, and the positions of the linker LK and the single molecule EN are also different (the product PD is omitted from the illustration). Other identical and similar parts will not be described repeatedly.

As shown in FIG. 1B, the passivation layer 130′ extends from the upper surface 100a of the substrate 100 onto a sidewall 1502′ of the hole 150′ and contacts a bottom surface 1501′. The protective layer 110′ and the hole 150′ partially overlap in the first direction D1, and the passivation layer 130′ and the hole 150′ do not overlap in the first direction D1. The linker LK is immobilized on the protective layer 110′ on the sidewall 1502′. In other embodiments, the passivation layer 130′ may extend into the hole 150′ and overlap with the hole 150′ in the first direction D1.

Referring to FIG. 1C, the sensing device 10″ differs from the sensing device 10 in that the configurations of a protective layer 110″ and a passivation layer 130″ of the sensing device 10″ are different from those of the protective layer 110 and the passivation layer 130 (the linker LK, the single molecule EN, and the product PD are omitted from the illustration), and the shape of the hole 150″ is different from the shape of the hole 150. Other identical and similar parts will not be described repeatedly.

As shown in FIG. 1C, the substrate 100, the protective layer 110″, and the passivation layer 130″ overlap each other in the first direction D1, and the protective layer 110″, the passivation layer 130″, and the hole 150″ at least partially overlap in the first direction D1. In the present embodiment, a deposition source for forming the protective layer 110″ is biased toward one side (e.g., the left side) of the hole 150″, such that the protective layer 110″ only covers a portion of the upper sidewall 1502″ and does not cover all of the sidewall 1502″ nor the bottom surface 1501″. In the cross-sectional view, the protective layer 110″ only covers the sidewall 1502″ on one side (e.g., the right side), and the pattern of the protective layer 110″ is not symmetrical with respect to the center of the hole 150″. An upper width W3 of the hole 150″ corresponding to the substrate 100 may be equal to a lower width W4, providing a cross-section similar to a rectangle.

It should be understood that the configurations of the protective layer 110 and the hole 150 in the sensing device 10P of FIG. 1D are not limited to being identical to those in the sensing device 10, but may be modified to the configurations of the protective layer 110′ and the hole 150′ in the sensing device 10′ of FIG. 1B, the configurations of the protective layer 110″ and the hole 150″ in the sensing device 10″ of FIG. 1C, or other suitable configurations.

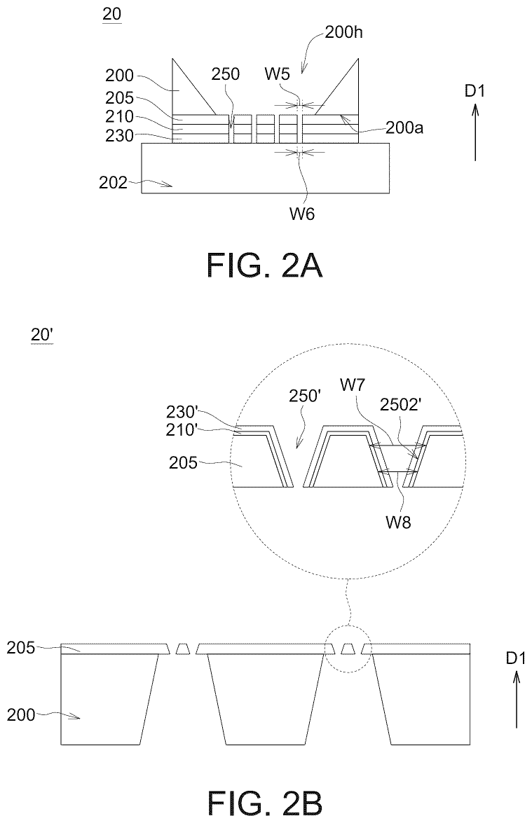

FIGS. 2A and 2B illustrate sensing devices 20 and 20′, respectively, in accordance with various embodiments of the present disclosure.

Referring to FIG. 2A, the difference between the sensing device 20 and the sensing device 10 is that the sensing device 20 further comprises a support layer 205 and a carrier substrate 202, and the hole 250 does not have a bottom surface and is formed at a different position than the hole 150. Other identical or similar parts will not be described in detail. Element symbols in FIG. 2A similar to those in FIG. 1A denote identical or similar elements having identical or similar materials and functions. FIGS. 2A-2B omit the illustration of the linker LK, the single molecule EN, and the product PD.

As shown in FIG. 2A, the sensing device 20 comprises a substrate 200, a support layer 205, a protective layer 210, a passivation layer 230, and a hole 250. The substrate 200 has an upper surface 200a and an opening 200h, wherein the opening 200h passes through the upper surface 200a. The support layer 205 is disposed on the substrate 200 and is in contact with the upper surface 200a. A protective layer 210 is disposed on the support layer 205. The passivation layer 230 is disposed on the protective layer 210. The hole 250 passes through the passivation layer 230, the protective layer 210, and the support layer 205, and is in communication with the opening 200h. That is, the hole 250 is a through-hole penetrating the support layer 205.

According to some embodiments, the substrate 200, the protective layer 210, and the passivation layer 230 overlap each other in a first direction D1, while the protective layer 210 and the passivation layer 230 do not overlap with the hole 250 in the first direction D1. That is, neither the protective layer 210 nor the passivation layer 230 extends into the hole 250. In other embodiments, the protective layer 210 and/or the passivation layer 230 may extend into the hole 250.

In the present embodiment, an upper width W5 of the hole 250 is equal to a lower width W6, having a substantially rectangular cross-section. In other embodiments, the upper width W5 may be different from the lower width W6.

According to some embodiments, the sensing device 20 further comprises a carrier substrate 202, wherein the carrier substrate 202 is in contact with the passivation layer 230, and the passivation layer 230, the protective layer 210, and the support layer 205 are disposed between the substrate 200 and the carrier substrate 202.

According to some embodiments, the material of the carrier substrate 202 may be similar to the material of the substrate 200. The material of the support layer 205 may comprise silicon nitride, but the present disclosure is not limited thereto.

Please refer to FIG. 2B. The difference between the sensing device 20′ and the sensing device 20 is that the sensing device 20′ does not have the carrier substrate 202, the protective layer 210′ extends into the hole 250′, and the shape of the hole 250′ is different from the shape of the hole 250; other identical or similar parts will not be described in detail again.

As shown in FIG. 2B, the hole 250′ includes a sidewall 2502′, and the protective layer 210′ extends onto the sidewall 2502′ of the hole 250′. In the present embodiment, the substrate 205, the protective layer 210′, and the passivation layer 230′ overlap each other in the first direction D1, and the protective layer 210′ at least partially overlaps with the hole 250′ in the first direction D1. The passivation layer 230′ covers the protective layer 210′ but does not extend into the hole 250′. However, the present disclosure is not limited thereto; in other embodiments, the passivation layer 230′ may also extend into the hole 250′ and contact the protective layer 210′ on the sidewall 2502′.

According to the present embodiment, an upper width W7 of the hole 250′ is greater than a lower width W8, having a substantially inverted trapezoidal cross-section. In other embodiments, the upper width W7 may be the same as the lower width W8.

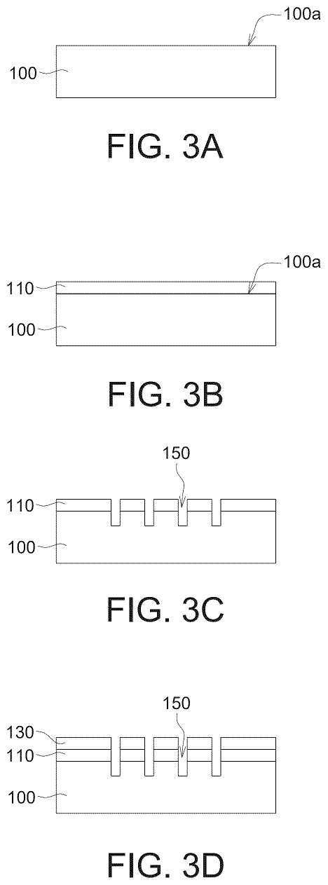

FIGS. 3A to 3D illustrate a method for manufacturing a sensing device according to the present disclosure, for example, illustrating sequential manufacturing steps, wherein the sensing devices 10 to 10″ can all be formed in the same or similar manner.

Please refer to FIG. 3A. Taking the sensing device 10 as an example, a substrate 100 is provided, and the substrate 100 has an upper surface 100a.

Please refer to FIG. 3B, a protective layer 110 is formed on the substrate 100, and the protective layer 110 is in contact with the upper surface 100a. The method for forming the protective layer 110 comprises a deposition process, and the deposition process may be atomic layer deposition (ALD), physical vapor deposition (PVD), chemical vapor deposition (CVD), or other suitable deposition methods.

Please refer to FIG. 3C, a hole 150 is formed, and the hole 150 passes through the protective layer 110 and a portion of the substrate 100. The method for forming the hole 150 comprises an etching process, and the etching process is focused ion beam (FIB), reactive ion etching (RIE), nanoimprint lithography (NIL), combined with Si wafer wet etching (KOH), extreme ultraviolet lithography (EUV), or other suitable etching methods.

Please refer to FIG. 3D, a passivation layer 130 is formed on the protective layer 110. The passivation layer 130 does not completely fill the hole 150; thus, the formed hole 150 also passes through the passivation layer 130. The method for forming the passivation layer 130 may include immersing the structure formed in FIG. 3C into a solution of the passivation layer material.

It should be understood that the formation steps and the formation sequence of the sensing devices 10 to 10″ of the present disclosure are not limited thereto and may further include other formation steps or other formation sequences. For example, the surface inside the hole 150 may also be modified with silanes to fix a single molecule (such as an enzyme). In some embodiments, an etching process may be performed on the substrate 100 first to form a hole 150″ passing through a portion of the substrate 100, and then a protective layer 110″ and a passivation layer 130″ are sequentially formed. Since the protective layer 110 and the passivation layer 130 do not completely fill the hole, the hole 150 also passes through the protective layer 110 and the passivation layer 130.

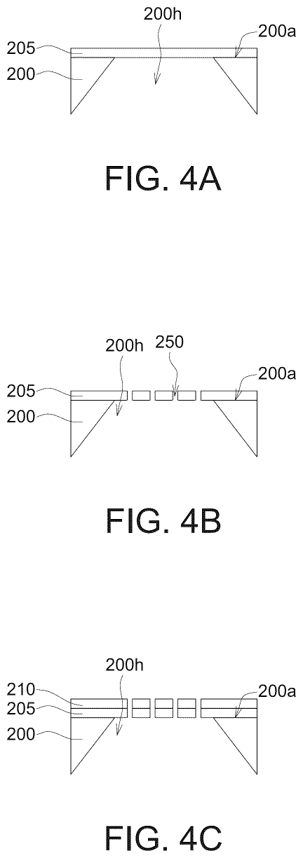

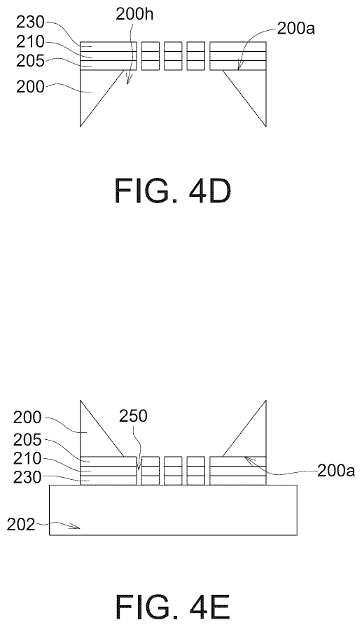

FIGS. 4A to 4E illustrate a method for manufacturing the sensing device 20 of FIG. 2A according to an embodiment of the present disclosure, for example, illustrating sequential manufacturing steps.

Please refer to FIG. 4A, a substrate 200 is provided, the substrate 200 having an upper surface 200a and an opening 200h. The opening 200h passes through the upper surface 200a. The opening 200h is formed, for example, by an etching process. Thereafter, a support layer 205 is formed on the substrate 200, and the support layer 205 is in contact with the upper surface 200a.

Please refer to FIG. 4B, a plurality of holes 250 are formed, and the holes 250 pass through the support layer 205 and are in communication with the opening 200h. The method for forming the holes 250 includes an etching process, and the etching process is focused ion beam (FIB) or dielectric breakdown.

Please refer to FIG. 4C, a protective layer 210 is formed on the support layer 205 through a deposition process. Specifically, different deposition processes will cause the formed protective layer 210 to be formed only on the support layer 205 or to extend to different parts of the sidewalls of the holes 250, which may have different aspects. For example, when the deposition process is atomic layer deposition (ALD), the protective layer 210 (not shown, and a passivation layer 230 may subsequently be provided), is also formed on the sidewalls and the bottoms of the holes 250. The thickness of the protective layer 210 is uniform, while it does not completely fill the holes 250, the shrinkage of hole can be controlled by controlling the thickness of the deposited protective layer 210. When the deposition process is chemical vapor deposition (CVD), the sidewalls and bottoms of the holes 250 will also have the protective layer 210 (not shown, and may subsequently have a passivation layer 230), and the thickness is less uniform compared to the protective layer formed by ALD. When the deposition process is physical vapor deposition (PVD), if the deposition source is not located directly above the hole 250 (i.e., it is offset), the sidewalls of the hole 250 will also have the protective layer 210 (not shown, and may subsequently have a passivation layer 230), and it is possible that only the sidewall on a single side of the hole has the protective layer (as shown by the protective layer 110″ in FIG. 1C).

Please refer to FIG. 4D, a passivation layer 230 is formed on the protective layer 210. The method for forming the passivation layer 230 may comprise immersing the structure formed in FIG. 4C into a solution of the passivation layer material. Since the protective layer 210 and the passivation layer 230 do not completely fill the holes 250, the holes 250 also pass through the protective layer 210 and the passivation layer 230.

Please refer to FIG. 4E, a carrier substrate 202 is provided, and the structure formed in FIG. 4C is flipped (e.g., upside down) and fixed onto the carrier substrate 202. The carrier substrate 202 is in contact with the passivation layer 230, and the passivation layer 230, the protective layer 210, and the support layer 205 are disposed between the substrate 100 and the carrier substrate 202.

It should be understood that the formation steps and the formation sequence of the sensing device 20 of the present disclosure are not limited thereto and may further include other formation steps or other formation sequences. For example, the surface inside the hole 250 may also be modified with silanes to fix a single molecule (such as an enzyme).

In order to make the above and other objects, features, and advantages of the present disclosure more apparent and easy to understand, several embodiments are listed below and described in detail as follows:

### Formation of Hole Arrays

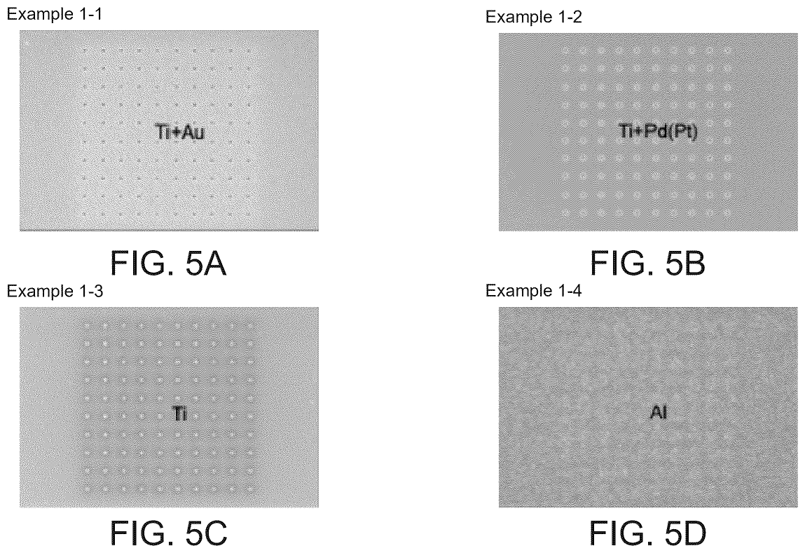

Please refer to FIGS. 5A-5D, which respectively show scanning electron microscope (SEM) images of hole arrays (also known as nanopore arrays) of different embodiments. The method for forming the hole arrays may include the following steps: using a fused glass substrate (thickness 170 μm); forming a protective layer on the glass substrate using PVD vacuum ion plating technology, where the thickness of the PVD coating layer is 50 nanometers; subsequently etching the hole array (for example, a 10×10 hole array) by focused ion beam (FIB), each hole passing through the protective layer and a portion of the substrate. Wherein, the protective layer of Example 1-1 in FIG. 5A is a titanium (Ti) layer and a gold (Au) layer stacked sequentially; the protective layer of Example 1-2 in FIG. 5B is a titanium layer and a palladium (Pd) layer stacked sequentially; the protective layer of Example 1-3 in FIG. 5C is a single titanium layer; and the protective layer of Example 1-4 in FIG. 5D is a single aluminum (Al) layer.

In addition to the representatively shown FIGS. 5A-5D, hole arrays of Examples 1-5 to 1-8 were also formed according to the same fabrication method, wherein the protective layer of Example 1-5 is a single aluminum oxide (Al₂O₃) layer, the protective layer of Example 1-6 is a single titanium dioxide (TiO₂) layer, the protective layer of Example 1-7 is a single hafnium dioxide (HfO₂) layer, and the protective layer of Example 1-8 is an aluminum oxide and titanium dioxide double layer.

The target aperture size for each hole is 100 nanometers. According to measurement results, the aperture size distribution of each hole in the aforementioned Examples 1-1 to 1-8 is mainly between 90 nanometers and 110 nanometers (100±10 nanometers).

### Influence of the Protective Layer on Photoluminescence Properties

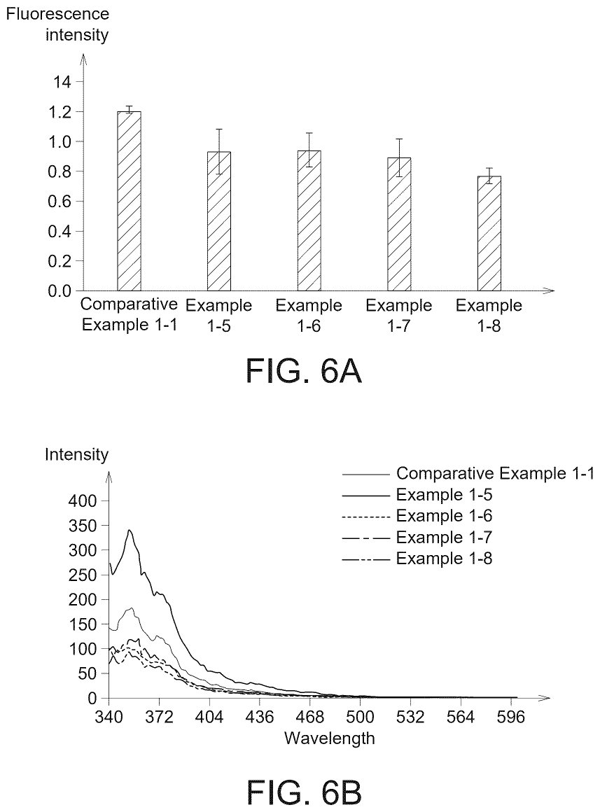

FIGS. 6A-6B illustrate the results of the photoluminescence properties of Comparative Example 1-1 and Examples 1-5 to 1-8. Examples 1-5 to 1-8 are hole arrays provided with a protective layer on the substrate as described above. Comparative Example 1-1 is a hole array without a protective layer on the substrate.

FIG. 6A presents the results of tests using fluorescent microspheres (Fluoresbrite® YG Carboxylate Microspheres, diameter 10 micrometers), wherein the excitation light wavelength is 450 nanometers and the emission light wavelength is 520 nanometers. As shown in FIG. 6A, the fluorescence emission value of Comparative Example 1-1 without a protective layer is around 1.2, while the other Examples 1-5 to 1-8 with protective layers all have lower emission values than Comparative Example 1-1. It can be seen that embodiments having a protective layer can reduce photoluminescence properties.

FIG. 6B presents the results of photoluminescence tests using excitation light with a wavelength of 325 nanometers. As shown in FIG. 6B, except for Example 1-5 (Al₂O₃), the other Examples 1-6 to 1-8 with protective layers all have lower photoluminescence intensity (emission light wavelength 356 nanometers) than Comparative Example 1-1, similarly verifying that some embodiments with protective layers can reduce photoluminescence properties.

### Influence of the Passivation Layer on Hydrophilicity

Since biomedical chips often need to be integrated with biomedical reagents, the chip surface requires high hydrophilicity characteristics. Therefore, the hydrophilicity of the substrate surface was further detected. In this disclosure, substrates of different embodiments having a protective layer were immersed in a solution containing a passivation layer material to allow the passivation layer to form on the protective layer, and the influence of the passivation layer on the hydrophilicity of the protective layer was tested.

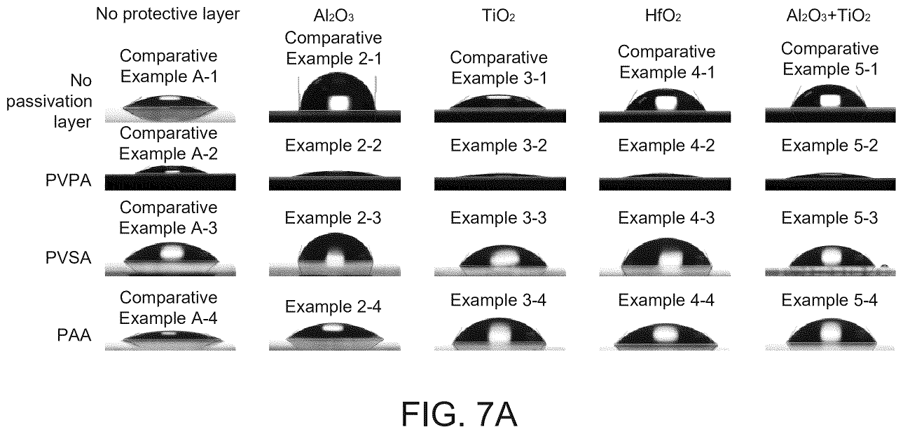

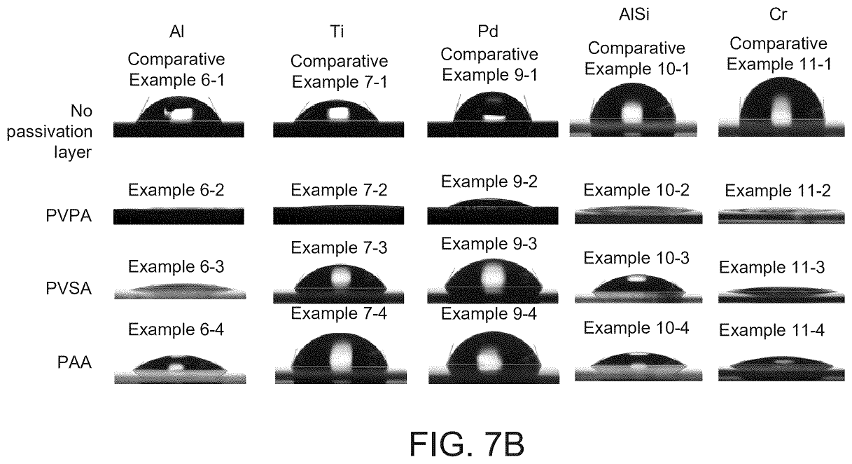

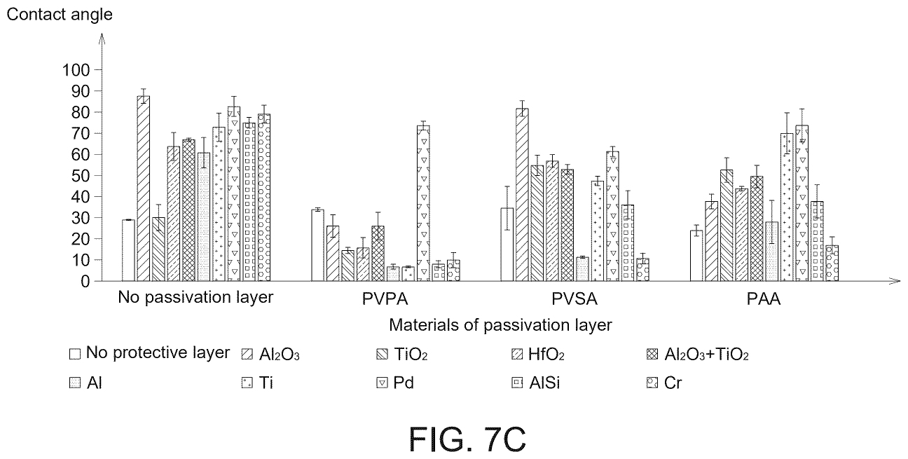

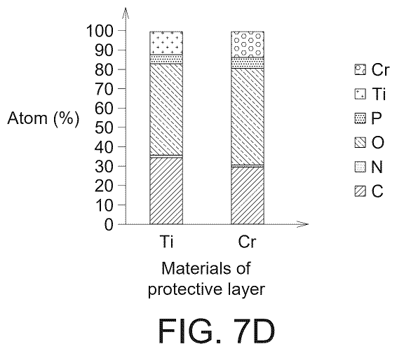

FIG. 7A shows schematic diagrams of water contact angle tests for Comparative Examples A-1 to A-4 and 2-1 to 5-1, and Examples 2-2 to 2-4, 3-2 to 3-4, 4-2 to 4-4, and 5-2 to 5-4. Comparative Examples A-1 to A-4 have no protective layer, and Comparative Examples A-1 and 2-1 to 5-1 have no passivation layer. Comparative Example 2-1 and Examples 2-2 to 2-4 have a protective layer of an aluminum oxide layer. Comparative Example 3-1 and Embodiments 3-2 to 3-4 have a protective layer of a titanium dioxide layer. Comparative Example 4-1 and Embodiments 4-2 to 4-4 have a protective layer of a hafnium dioxide layer. Comparative Example 5-1 and Examples 5-2 to 5-4 have a protective layer of aluminum oxide and titanium dioxide. Comparative Example A-2 and Examples 2-2 to 5-2 have a passivation layer of PVPA. Comparative Example A-3 and Examples 2-3 to 5-3 have a passivation layer of PVSA. Comparative Example A-4 and Examples 2-4 to 5-4 have a passivation layer of PAA.

In FIG. 7A, the protective layer is formed on the glass substrate by atomic layer deposition (ALD), after which the surface is modified with a passivation layer as required for various tests. The passivation layer modification is performed by surface cleaning with oxygen plasma for 5 minutes, followed by immersion in a solution of passivation layer material (PVPA, PVSA, or PAA) heated to 90 degrees for 2 minutes. This is followed by rinsing with pure water, drying with nitrogen, and placing on an 80° C. hot plate for annealing for 10 minutes to complete the surface modification. Thereafter, the water contact angle test is performed. The water contact angle test is conducted by dropping water onto the modified substrate surface, observing the droplet shape, and calculating its contact angle. A contact angle greater than 90 degrees indicates that the surface contacted by the water droplet is hydrophobic; conversely, the smaller the contact angle, the more hydrophilic the surface, and smaller than 10 degrees can be called a superhydrophilic surface. The passivation layer materials are relatively hydrophilic; if they are successfully plated onto the aforementioned surfaces, the surfaces will exhibit a more hydrophilic state.

From the results in FIG. 7A, it can be seen that because Comparative Example A-2 and Examples 2-2 to 5-2 have a PVPA passivation layer, they have smaller water contact angles and higher surface hydrophilicity. Wherein, compared to Comparative Example A-2, Examples 2-2, 3-2, 4-2, and 5-2 with the passivation layer produce a more significant hydrophilic effect, indicating that PVPA can successfully perform surface modification on the above four protective layer materials (i.e., aluminum oxide, titanium dioxide, hafnium dioxide, and a mixture of aluminum oxide and titanium dioxide).

FIG. 7B shows schematic diagrams of water contact angle tests for Comparative Examples 6-1 to 11-1 and Examples 6-2 to 6-4, 7-2 to 7-4, 8-2 to 8-4, 9-2 to 9-4, 10-2 to 10-4, and 11-2 to 11-4. Comparative Examples 6-1 to 11-1 have no passivation layer. Comparative Example 6-1 and Examples 6-2 to 6-4 have a protective layer of an aluminum (Al) layer. Comparative Example 7-1 and Examples 7-2 to 7-4 have a protective layer of a titanium (Ti) layer. Comparative Example 9-1 and Examples 9-2 to 9-4 have a protective layer of a palladium (Pd) layer. Comparative Example 10-1 and Examples 10-2 to 10-4 have a protective layer of aluminum silicide (AlSi), and Comparative Example 11-1 and Examples 11-2 to 11-4 have a protective layer of chromium (Cr). Examples 6-2 to 11-2 have a PVPA passivation layer. Examples 6-3 to 11-3 have a PVSA passivation layer. Examples 6-4 to 11-4 have a PAA passivation layer. According to some embodiments, in the aluminum silicide protective layer, the range of parts by weight of silicon is between 0.5 and 20, and the range of parts by weight of aluminum is between 80 and 99.5. According to one embodiment, the range of parts by weight of silicon is between 1 and 12, and the range of parts by weight of aluminum is between 88 and 99. According to one embodiment, the parts by weight of silicon is 1, the parts by weight of aluminum is 99, and the weight ratio of silicon to aluminum is 1:99.

In FIG. 7B, the protective layer is formed by physical vapor deposition (PVD), after which the passivation layer modification as described above is performed, and the water contact angle test as described above is performed.

From the results in FIG. 7B, it can be seen that because Examples 7-2, 9-2, 10-2, and 11-2 have a PVPA passivation layer, they have smaller water contact angles and higher surface hydrophilicity. It can be seen that the PVPA passivation layer can successfully perform surface modification on protective layer materials having aluminum, titanium, palladium, aluminum silicide, and chromium.

FIG. 7C shows the test results of water contact angles for different comparative examples and embodiments, namely comparing Comparative Examples A-1 to A-4 and 2-1 to 5-1 and Examples 2-2 to 2-4, 3-2 to 3-4, 4-2 to 4-4, 5-2 to 5-4 as described in FIG. 7A, and Comparative Examples 6-1 to 11-1 and Examples 6-2 to 6-4, 7-2 to 7-4, 8-2 to 8-4, 9-2 to 9-4, 10-2 to 10-4, and 11-2 to 11-4 as described in FIG. 7B.

The results of the water contact angle tests in FIG. 7C are summarized and simplified as presented in Table 1 below. In Table 1, data where the average water contact angle is between 10 degrees and 30 degrees is represented by “+”, data where the average water contact angle is less than 10 degrees is represented by “++”, and other data where the contact angle is greater than 30 degrees is not marked with any symbol.

TABLE 1

| | No passivation | | | |
|---|---|---|---|---|
| | layer | passivation | passivation | passivation |
| Protective | (Comparative | layer of | layer of | layer of |
| layer | Example) | PVPA | PVSA | PAA |
| No protective layer | + | | | + |
| (Comparative Example) | | | | |
| Al₂O₃ | | + | | |
| TiO₂ | + | + | | |
| HfO₂ | | + | | |
| Al₂O₃ + TiO₂ | | + | | |
| Al | | ++ | + | + |
| Ti | | ++ | | |
| Pd | | | | |
| AlSi | | ++ | | |
| Cr | | + | + | + |

From the results shown in FIG. 7C and Table 1, it can be seen that, except for palladium, the passivation layer of PVPA has an affinity for most materials of the protective layer, and thus can provide a more hydrophilic substrate surface.

FIG. 7D illustrates the surface elemental composition analysis of Examples 7-2 and 11-2.

As previously described, Example 7-2 has a protective layer of a titanium layer and a passivation layer of PVPA, and Example 11-2 has a protective layer of a chromium layer and a passivation layer of PVPA. Surface elemental composition analysis was performed on Examples 7-2 and 11-2 using X-ray Photoelectron Spectroscopy (XPS) to confirm whether the surfaces were successfully modified by the passivation layer.

From FIG. 7D, it can be seen that both Examples 7-2 and 11-2 contain the element phosphorus (P), indicating that the passivation layers of both PVPA and PVSA were successfully modified on these two types of protective layers (Ti or Cr).

Based on the combined results of FIGS. 7A to 7D, the affinity of the protective layers of various materials for the passivation layer can be summarized in Table 2 below. In Table 2, “V” indicates that the substrate or the protective layer has an excellent affinity for the passivation layer, which is beneficial for subsequent applications.

TABLE 2

| | passivation | passivation | passivation |
|---|---|---|---|
| Protective | layer of | layer of | layer of |
| layer | PVPA | PVSA | PAA |
| No protective layer | V | | V |
| (Comparative Example) | | | |
| Al₂O₃ | V | V | V |
| TiO₂ | V | | |
| HfO₂ | V | | V |
| Al₂O₃ + TiO₂ | V | | |
| Al | V | V | |
| Ti | V | V | |
| Pd | | | |
| AlSi | V | | |
| Cr | V | V | V |

Note:
The affinity of PAA was evaluated only by water contact angle (the affinities of PVPA and PVSA were evaluated by both water contact angle and elemental composition analysis).

### Effect of Passivation Layer on Adhesion Level

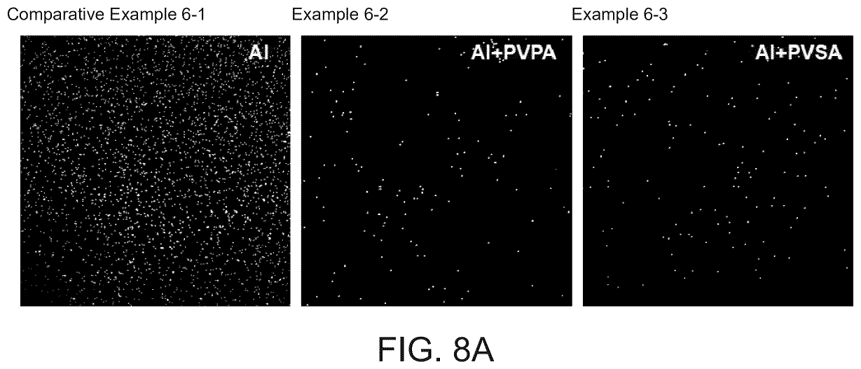

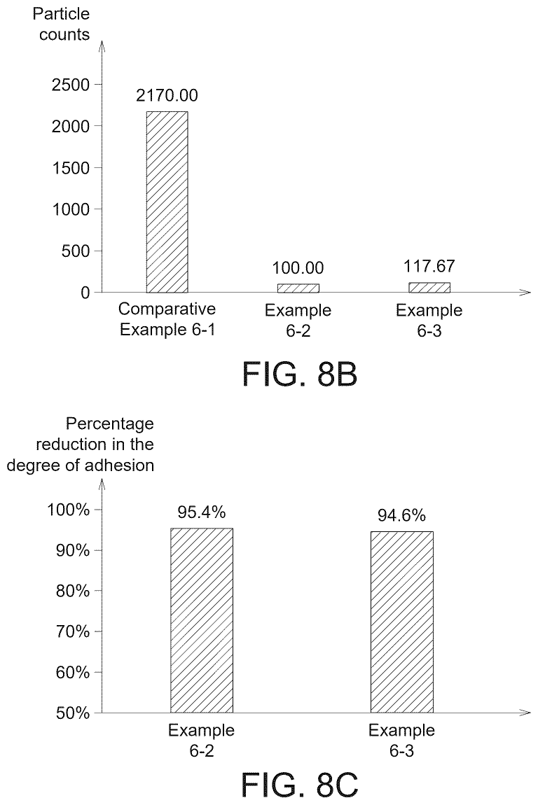

FIG. 8A shows images of the adhesion level of proteins (bound to fluorescent spheres) for Comparative Example 6-1 and Examples 6-2 to 6-3. FIG. 8B shows the particle counts of fluorescent spheres for Comparative Example 6-1 and Examples 6-2 to 6-3. FIG. 8C shows the percentage reduction in the degree of adhesion (i.e., the percentage reduction in the number of fluorescent sphere particles) for Examples 6-2 to 6-3 relative to Comparative Example 6-1.

As previously described, Comparative Example 6-1 and Examples 6-2 to 6-3 have a protective layer of an aluminum layer; Comparative Example 6-1 has no passivation layer, Example 6-2 has a passivation layer of PVPA, and Example 6-3 has a passivation layer of PVSA. Adhesion tests were performed on Comparative Example 6-1 and Examples 6-2 to 6-3. Neutravidin was used as a protein example for the adhesion test. It was added to the surface of the modified chip (substrate) and then washed away; then, fluorescent spheres with biotin on their surfaces were added. Biotin and Neutravidin bind to each other, thereby allowing observation of whether Neutravidin protein remains or adheres. After taking photos with a fluorescence microscope, the number of fluorescent spheres in the frame was calculated using the image processing software ImageJ. The difference in the number of fluorescent spheres before and after the modification of the passivation layer was calculated, and this difference was divided by the number of fluorescent spheres before modification to calculate the percentage reduction in the number of fluorescent spheres, thereby estimating the extent to which the passivation layer reduces protein adhesion and non-specific adsorption (as shown in FIG. 8C).

From FIGS. 8A to 8C, it can be seen that the protective layer consisting solely of an aluminum layer (Comparative Example 6-1) has the largest number of fluorescent spheres and adheres to many proteins. Examples 6-2 to 6-3, which are modified with a passivation layer, can all significantly reduce the number of fluorescent spheres and significantly reduce the level of protein adhesion.

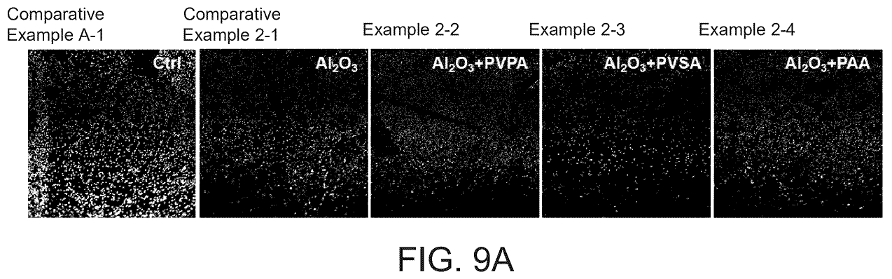

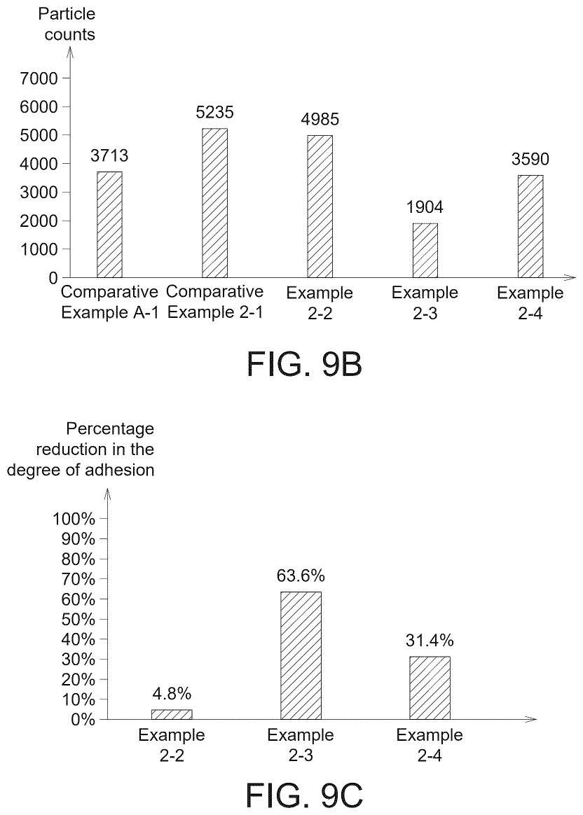

FIG. 9A shows images of the adhesion level of proteins (bound to fluorescent spheres) for Comparative Examples A-1, 2-1 and Examples 2-2 to 2-4. FIG. 9B shows the particle counts of fluorescent spheres for Comparative Examples A-1, 2-1 and Examples 2-2 to 2-4. FIG. 9C shows the percentage reduction in the degree of adhesion (i.e., the percentage reduction in the number of fluorescent sphere particles) for Examples 2-2 to 2-4 relative to Comparative Example 2-1.

As previously described, Comparative Example A-1 has no protective layer or passivation layer; Comparative Example 2-1 and Examples 2-2 to 2-4 have a protective layer of an aluminum oxide layer; Example 2-2 has a passivation layer of PVPA, Example 2-3 has a passivation layer of PVSA, and Example 2-4 has a passivation layer of PAA. Adhesion tests as described above were performed on Comparative Examples A-1, 2-1 and Examples 2-2 to 2-4.

From FIGS. 9A to 9C, it can be seen that the protective layer consisting solely of an aluminum oxide layer (Comparative Example 2-1) has a larger number of fluorescent spheres and adheres to many proteins. Examples 2-2 to 2-4, modified with a passivation layer, can all reduce the number of fluorescent spheres and reduce the level of protein adhesion.

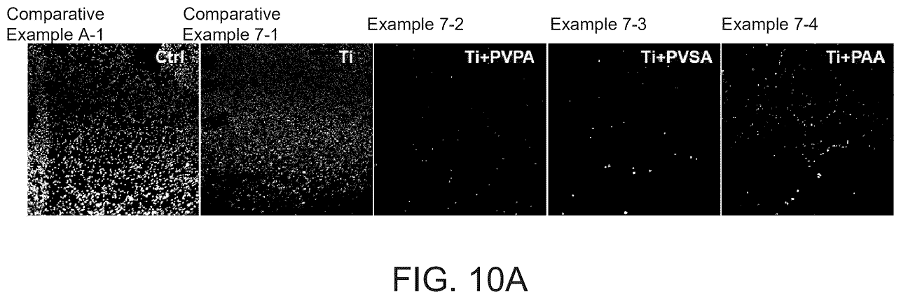

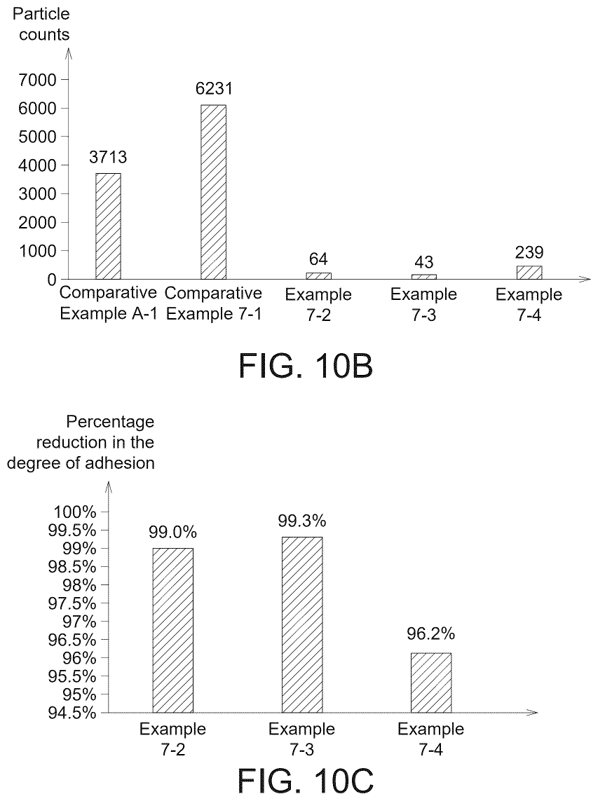

FIG. 10A shows images of the adhesion level of proteins (bound to fluorescent spheres) for Comparative Examples A-1, 7-1 and Examples 7-2 to 7-4. FIG. 10B shows the particle counts of fluorescent spheres for Comparative Examples A-1, 7-1 and Examples 7-2 to 7-4. FIG. 10C shows the percentage reduction in the degree of adhesion (i.e., the percentage reduction in the number of fluorescent sphere particles) for Examples 7-2 to 7-4 relative to Comparative Example 7-1.

As previously described, Comparative Example A-1 has no protective layer or passivation layer; Comparative Example 7-1 and Examples 7-2 to 7-4 have a protective layer of a titanium layer; Example 7-2 has a passivation layer of PVPA, Example 7-3 has a passivation layer of PVSA, and Example 7-4 has a passivation layer of PAA. Adhesion tests as described above were performed on Comparative Examples A-1, 7-1 and Examples 7-2 to 7-4.

From FIGS. 10A to 10C, it can be seen that the protective layer consisting solely of a titanium layer (Comparative Example 7-1) has a larger number of fluorescent spheres and adheres to many proteins. Examples 7-2 to 7-4, modified with a passivation layer, can all significantly reduce the number of fluorescent spheres and significantly reduce the level of protein adhesion.

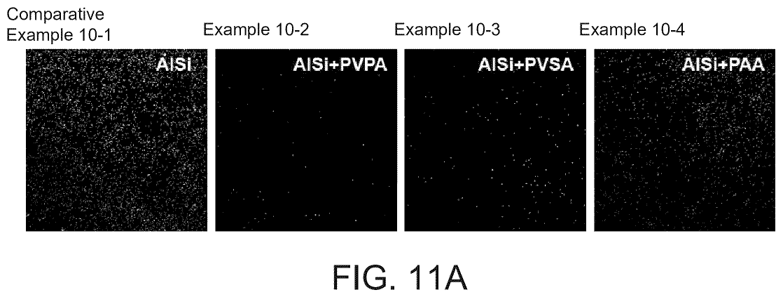

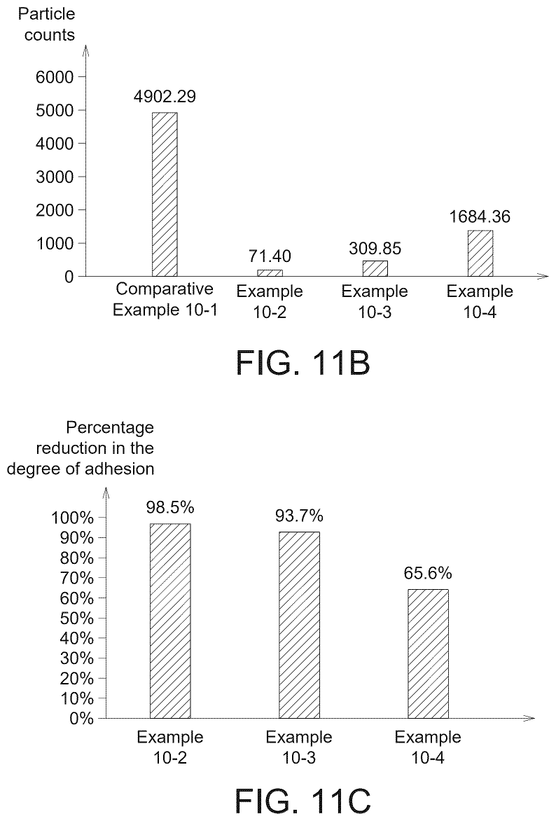

FIG. 11A shows images of the adhesion level of proteins (bound to fluorescent spheres) for Comparative Example 10-1 and Examples 10-2 to 10-4. FIG. 11B shows the particle counts of fluorescent spheres for Comparative Example 10-1 and Examples 10-2 to 10-4. FIG. 11C shows the percentage reduction in the degree of adhesion (i.e., the percentage reduction in the number of fluorescent sphere particles) for Examples 10-2 to 10-4 relative to Comparative Example 10-1.

As previously described, Comparative Example 10-1 and Examples 10-2 to 10-4 have a protective layer of an aluminum silicide layer; Example 10-2 has a passivation layer of PVPA, Example 10-3 has a passivation layer of PVSA, and Example 10-4 has a passivation layer of PAA. Adhesion tests as described above were performed on Comparative Example 10-1 and Examples 10-2 to 10-4.

From FIGS. 11A to 11C, it can be seen that the protective layer consisting solely of an aluminum silicide layer (Comparative Example 10-1) has a larger number of fluorescent spheres and adheres to many proteins. Examples 10-2 to 10-4, modified with a passivation layer, can all significantly reduce the number of fluorescent spheres and significantly reduce the level of protein adhesion.

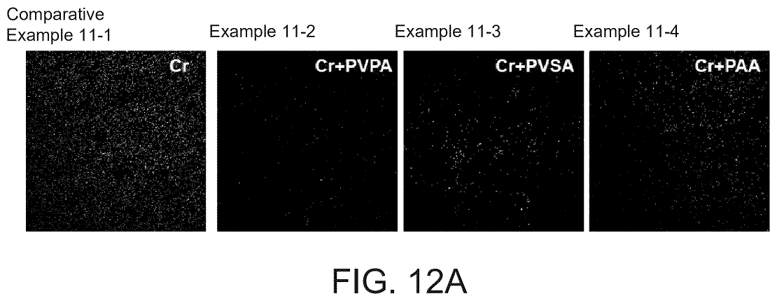

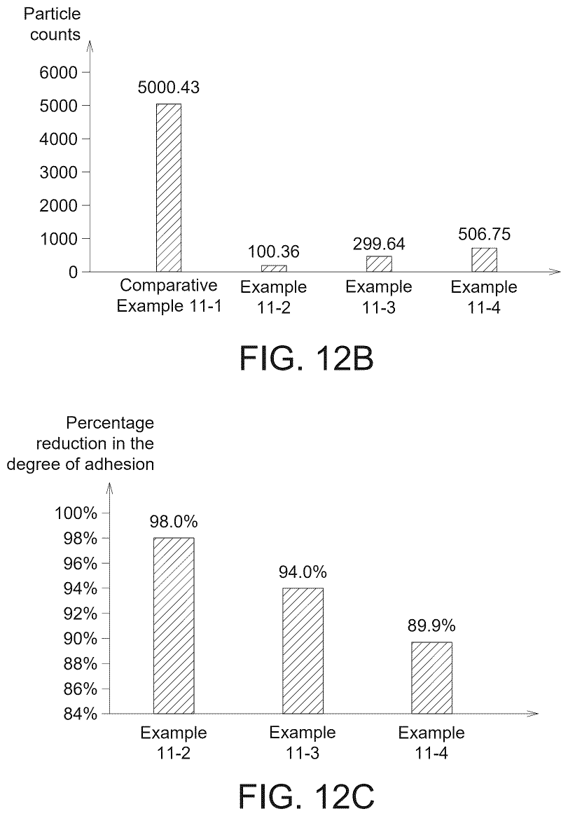

FIG. 12A shows images of the adhesion level of proteins (bound to fluorescent spheres) for Comparative Example 11-1 and Examples 11-2 to 11-4. FIG. 12B shows the particle counts of fluorescent spheres for Comparative Example 11-1 and Examples 11-2 to 11-4. FIG. 12C shows the percentage reduction in the degree of adhesion (i.e., the percentage reduction in the number of fluorescent sphere particles) for Examples 11-2 to 11-4 relative to Comparative Example 11-1.

As previously described, Comparative Example 11-1 and Examples 11-2 to 11-4 have a protective layer of a chromium layer; Example 11-2 has a passivation layer of PVPA, Example 11-3 has a passivation layer of PVSA, and Example 11-4 has a passivation layer of PAA. Adhesion tests as described above were performed on Comparative Example 11-1 and Examples 11-2 to 11-4.

From FIGS. 12A to 12C, it can be seen that the protective layer consisting solely of a chromium layer (Comparative Example 11-1) has a larger number of fluorescent spheres and adheres to many proteins. Examples 11-2 to 11-4, modified with a passivation layer, can all significantly reduce the number of fluorescent spheres and significantly reduce the level of protein adhesion.

### Effect of Passivation Layer on Non-specific Adhesion

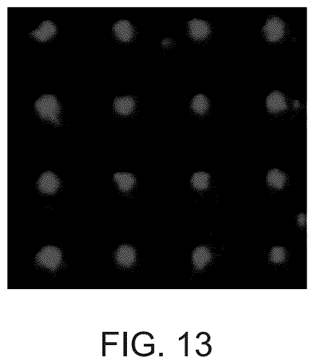

FIG. 13 shows the results of a DNA synthesis sequencing reaction after immobilizing enzymes in nanopores.

In FIG. 13, a nanopore array chip is plated with a protective layer of titanium and modified with a passivation layer of PVPA. After the modification with the passivation layer, the nanopores (the portions of the surface without the passivation layer) are modified with biotin, and a sequencing enzyme (e.g., polymerase) is immobilized in the pores using biotin-streptavidin before performing a DNA synthesis reaction. After the overnight DNA synthesis reaction, the DNA is stained with a fluorescent dye to observe the signals of the nanopore array. The signals emitted from the nanopore array can be seen after DNA staining, indicating that the sequencing enzyme can complete the DNA synthesis reaction within the nanopores. Specifically, the method of modification with biotin involves first modifying the amine groups (—NH₂) onto the glass substrate exposed in the nanopores using 2% (3-Aminopropyl)triethoxysilane (APTES), and then adding biotin NHS-PEG-Biotin containing an NHS group and a PEG derivative (purchased from Thermo Scientific). The NH₂ reacts with the NHS to form a covalent bond, thereby achieving the effect of immobilizing biotin within the pores.

As shown in FIG. 13, most of the fluorescent signals are located in the pore array, with only scattered signals showing non-specific adhesion or attachment, indicating that the modification technology using the protective layer and the passivation layer can significantly reduce non-specific attachment of enzymes and DNA.

### Image Observation

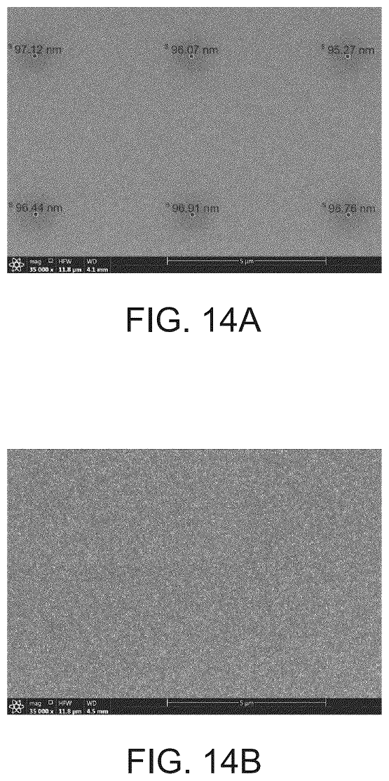

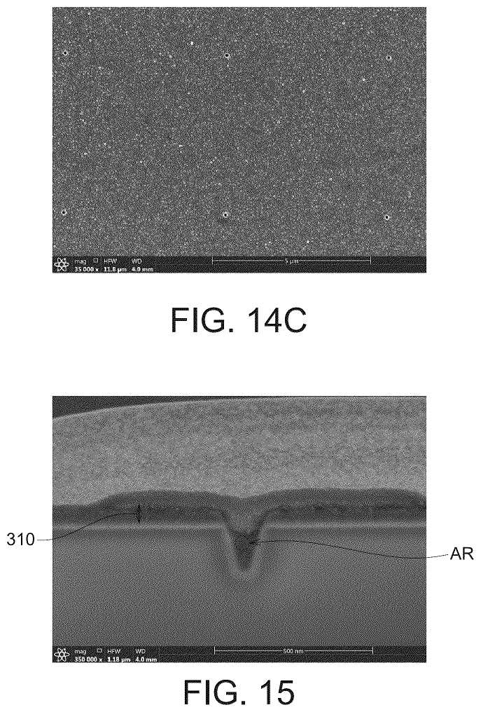

FIGS. 14A to 14C are schematic diagrams of the SEM surface roughness at the early, middle, and late stages of the substrate surface treatment, respectively.

As shown in FIG. 14A, the roughness of the pure metal protective layer is small (early stage). As shown in FIG. 14B, the roughness becomes slightly larger after modification with the PVPA passivation layer (middle stage). As shown in FIG. 14C, the roughness becomes even larger after the modification with Biotin-PEG5000-NH₂ and the distribution of 40 nm fluorescent particles (late stage); the results show differentiated surface morphologies after modification.

FIG. 15 shows an image of a single fluorescent particle entering a pore.

In FIG. 15, the substrate is a fused glass substrate. Cross-sectional inspection was performed on the prepared PVD metal film layer (Cr) (as the protective layer 310) and the position of the hole drilled by a focused ion beam (FIB). Before analyzing the cross-sectional structure of the sample, the chip was sliced using a focused ion beam, and then detailed observation and analysis were performed on the slices to confirm the structure and contents between each layer of the chip.

As indicated by the arrow AR in FIG. 15, a single fluorescent particle (40 nm) can be observed entering the pore.

In summary, the present disclosure provides an improved sensing device and a method for manufacturing the same. The protective layer of the sensing device provides protection for the substrate and reduces background interference signals during detection, thereby inhibiting the corrosion of the substrate by biomedical reagents containing salts. The protective layer can also reduce interference from the photoluminescence characteristics of the substrate or the background, diminishing the impact of background values on the sensing signal during sensing. The passivation layer can reduce non-specific adsorption during the detection process. The hole has a specific modification region providing for the immobilization modification of a detection substance, such as an enzyme, a protein, a peptide, a nucleic acid, or other suitable detection substances. The arrangement of the holes can appropriately separate the detection substances in space, preventing interference between sensing signals that makes it difficult to distinguish the true signals of adjacent detection substances when they are too close to each other. Accordingly, the sensing device of the present disclosure not only satisfies the requirements for reducing photoluminescence characteristics and non-specific adsorption of biomedical chips but also achieves the high hydrophilicity required for biomedical chips, and can further avoid situations where sensing signals interfere with each other due to detection substances being too close to one another.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A sensing device comprising:
a substrate having an upper surface;
a protective layer disposed on the substrate and contacting the upper surface; and
a hole penetrating the protective layer and a portion of the substrate.

2. The sensing device according to claim 1, wherein the hole comprises a bottom surface and a sidewall, the sidewall is connected to the bottom surface, the bottom surface exposes the substrate, and the protective layer extends from the upper surface of the substrate onto the sidewall of the hole.

3. The sensing device according to claim 2, wherein the protective layer is separated from the bottom surface of the hole.

4. The sensing device according to claim 2, wherein the protective layer further extends to the bottom surface of the hole.

5. A sensing device comprising:
a substrate having an upper surface;
a protective layer disposed on the substrate and contacting the upper surface;
a passivation layer disposed on the protective layer; and
a hole penetrating the passivation layer, the protective layer and a portion of the substrate.

6. The sensing device according to claim 5, wherein the hole comprises a bottom surface and a sidewall, the sidewall is connected to the bottom surface, the bottom surface exposes the substrate, and the protective layer extends from the upper surface of the substrate onto the sidewall of the hole.

7. The sensing device according to claim 6, wherein the protective layer is separated from the bottom surface of the hole.

8. The sensing device according to claim 5, wherein the substrate, the protective layer, and the passivation layer are overlapping with each other in a first direction, while the passivation layer and the hole are non-overlapping in the first direction.

9. The sensing device according to claim 5, wherein the substrate, the protective layer, and the passivation layer are overlapping with each other in a first direction, while the passivation layer and the hole are at least partially overlapping in the first direction.

10. The sensing device according to claim 1, wherein the substrate is a silicon-based substrate.

11. The sensing device according to claim 10, wherein the silicon-based substrate comprises a material, and the material is silicon, silicon dioxide, silicon nitride, or glass.

12. The sensing device according to claim 1, wherein the protective layer comprises a material, and the material is metal oxide, metal, or a combination thereof.

13. The sensing device according to claim 12, wherein the metal oxide is aluminum oxide, titanium dioxide, hafnium dioxide, or any combination thereof.

14. The sensing device according to claim 13, wherein the metal is aluminum, aluminum silicide, titanium, chromium, palladium or any combination thereof.

15. The sensing device according to claim 1, wherein the passivation layer comprises an acidic polymer.

16. The sensing device according to claim 15, wherein the acidic polymer is poly(vinylphosphonic acid), poly(vinylsulfonic acid) or poly(acrylic acid).

17. The sensing device according to claim 1, wherein a number of the hole is plural, and the holes are arranged as an array.

18. The sensing device according to claim 1, further comprising a linker and a single molecule, wherein the single molecule is immobilized in the hole through the linker.

19. A method for manufacturing a sensing device, comprising:
providing a substrate having an upper surface;
forming a protective layer on the upper surface, and the protective layer contacting the upper surface;
forming a passivation layer on the protective layer; and
forming a hole penetrating the passivation layer, the protective layer and a portion of the substrate.

20. The method for manufacturing a sensing device according to claim 19, wherein a method for forming the protective layer comprises a deposition process, the deposition process comprises atomic layer deposition, chemical vapor deposition, or physical vapor deposition.

21. The method for manufacturing a sensing device according to claim 19, wherein a method for forming the hole comprises an etching process, and the etching process comprises focused ion beam or extreme ultraviolet lithography.

22. The sensing device according to claim 5, wherein the substrate is a silicon-based substrate.

23. The sensing device according to claim 22, wherein the silicon-based substrate comprises a material, and the material is silicon, silicon dioxide, silicon nitride, or glass.

24. The sensing device according to claim 5, wherein the protective layer comprises a material, and the material is metal oxide, metal, or a combination thereof.

25. The sensing device according to claim 24, wherein the metal oxide is aluminum oxide, titanium dioxide, hafnium dioxide, or any combination thereof.

26. The sensing device according to claim 24, wherein the metal is aluminum, aluminum silicide, titanium, chromium, and palladium or any combination thereof.

27. The sensing device according to claim 5, wherein the passivation layer comprises an acidic polymer.

28. The sensing device according to claim 27, wherein the acidic polymer is poly(vinylphosphonic acid), poly(vinylsulfonic acid) or poly(acrylic acid).

29. The sensing device according to claim 5, wherein a number of the hole is plural, and the holes are arranged as an array.

30. The sensing device according to claim 5, further comprising a linker and a single molecule, wherein the single molecule is immobilized in the hole through the linker.
